(19) United States
(12) Patent Application Publication
(10) Pub. No.: US 2019/0169496 A1
(43) Pub. Date: Jun. 6, 2019

(54) RED PHOSPHOR AND LIGHT EMITTING DEVICE COMPRISING SAME

(71) Applicant: LG INNOTEK CO., LTD., Seoul (KR)

(72) Inventors: Ji Wook MOON, Seoul (KR); Woo Seuk SONG, Seoul (KR); Bong Kul MIN, Seoul (KR)

(73) Assignee: LG INNOTEK CO., LTD., Seoul (KR)

(21) Appl. No.: 15/755,008

(22) PCT Filed: Aug. 25, 2016
(86) PCT No.: PCT/KR2016/009468

§ 371 Date: Feb. 23, 2018

(30) Foreign Application Priority Data
Aug. 25, 2015 (KR) 10-2015-0119657
Aug. 25, 2015 (KR) 10-2015-0119658

(51) Int. Cl. C09K 11/57; C09K 11/02; H01L 33/50; H01L 33/32; H01L 33/62; H01L 33/38

(52) U.S. Cl. CPC C09K 11/57; C09K 11/02; H01L 33/38; H01L 33/325; H01L 33/62; H01L 33/502

(57) ABSTRACT

An embodiment provides a red phosphor satisfying the following structural formula and a light emitting device including the same.

K₂M₁₋ₓMn⁴⁺_{X}F₆ [Structural Formula]

Here, M is at least one element selected from the group consisting of a Group IV element and a Group XIV element, and X satisfies 0.028≤X≤0.055.

### TECHNICAL FIELD

An embodiment relates to a red phosphor and a light emitting device including the same.

### BACKGROUND ART

A light emitting device (LED) is a compound semiconductor element configured to convert electric energy into light energy, and may realize various colors by adjusting a composition ratio of the compound semiconductor.

A nitride semiconductor LED has advantages of low power consumption, semi-permanent lifetime, fast response speed, safety, and environmental friendliness compared to conventional light sources such as fluorescent lamps and incandescent lamps. Accordingly, it has been expanding applications such as a light-emitting diode backlight which replaces a cold cathode fluorescent lamp (CCFL) constituting a backlight of a liquid crystal display (LCD) device, white light-emitting diode lighting device which may replace the fluorescent lamp or the incandescent lamp, automotive headlights, and up to traffic lights.

A light emitting device may implement white light by combining an LED (light-emitting chip) and a phosphor. Nowadays, a K₂SiF₆ phosphor as a red phosphor has been studied. However, such a fluoride phosphor has a problem that photoluminescence decreases or color coordinates change under a high temperature and high humidity environment.

### DISCLOSURE

### Technical Problem

An embodiment provides a red phosphor having excellent reliability and a light emitting device using the red phosphor.

Problems to be solved in embodiments are not limited thereto, and objects and effects which may be determined from solutions to the problems and embodiments described below are also included.

### Technical Solution

One aspect of the present invention provides a red phosphor satisfies a following structural formula.

K₂M₁₋ₓMn⁴⁺ₓF₆ [Structural Formula]

Here, M is at least one element selected from the group consisting of a Group IV element and a Group XIV element, and the X satisfies 0.028≤X≤0.055.

The red phosphor may include a coating layer formed on a surface.

The coating layer may include a Group II or Group III element.

The coating layer may include at least one of MgO, In₂O₃, Al₂O₃, and B₂O₃.

Another aspect of the present invention provides a light emitting device, including a light emitting device (LED) configured to emit first light; and a wavelength conversion layer configured to convert a wavelength of the first light, wherein the wavelength conversion layer includes: a first phosphor configured to absorb the first light to emit light in a green wavelength range; and a second phosphor configured to absorb the first light to emit light in a red wavelength range, wherein the second phosphor satisfies a following structural formula.

K₂M₁₋ₓMn⁴⁺_{X}F₆ [Structural Formula]

Here, M is at least one element selected from the group consisting of a Group IV element and a Group XIV element, and the X satisfies 0.028≤X≤0.055.

The wavelength conversion layer may include a light-transmissive resin in which the first wavelength converter and the second wavelength converter are dispersed.

A total amount of the first wavelength converter and the second wavelength converter may be 25 to 50 wt % based on 100 wt % of a composition of the wavelength conversion layer.

A total amount of the first wavelength converter and the second wavelength converter may be 25 to 45 wt % based on 100 wt % of a composition of the wavelength conversion layer.

A content ratio of the first wavelength converter may be 25 to 40%, and a content ratio of the second wavelength converter may be 60 to 75%.

A molar ratio of Mn of the second wavelength converter may be 0.04 to 0.055 mol.

A total amount of the first wavelength converter and the second wavelength converter may be 30 to 50 wt % based on 100 wt % of a composition of the wavelength conversion layer.

A content ratio of the first wavelength converter may be 15 to 30%, and a content ratio of the second wavelength converter may be 70 to 85%.

A molar ratio of Mn of the second wavelength converter may be 0.028 to 0.399 mol.

The second phosphor may include a coating layer formed on a surface.

The coating layer may include at least one of MgO, In₂O₃, Al₂O₃, and B₂O₃.

### Advantageous Effects

According to an embodiment, a moisture resistance of a red phosphor may be improved. Accordingly, a decrease of photoluminescence can be controlled under a high temperature and high humidity environment.

In addition, a change of color coordinates can be controlled under a high temperature and high humidity environment.

Various and beneficial advantages and effects of the present invention are not limited to the above description, and can be more easily understood while describing a detailed embodiment of the present invention.

### DESCRIPTION OF DRAWINGS

FIG. 1 is a conceptual diagram of a red phosphor according to an embodiment of the present invention,

FIG. 2 is a scanning electron microscope (SEM) photograph of a red phosphor coated with MgO using an ODE solution,

FIG. 3 is an SEM photograph of a red phosphor coated with In₂O₃ using an ODE solution,

FIG. 4 is an SEM photograph of a red phosphor coated with Al₂O₃ using an IPA solution,

FIG. 5 is an SEM photograph of a red phosphor coated with In₂O₃ using a PEG solution,

FIG. 6 is an SEM photograph of a red phosphor coated with Al₂O₃ using a PEG solution,

FIG. 7 is an SEM photograph of a red phosphor coated with B₂O₃ using a PEG solution,

FIG. 8 is a conceptual diagram of a light emitting device according to an embodiment of the present invention,

FIG. 9 is a graph illustrating color coordinates of white light implemented using a red phosphor having a molar ratio of Mn of 100% and 75%,

FIG. 10 is a graph illustrating luminous flux of white light implemented using a red phosphor having a molar ratio of Mn of 100% and 75%,

FIG. 11 is a graph illustrating a spectrum of white light implemented using a red phosphor having a molar ratio of Mn of 100% and 75%,

FIG. 12 is a graph illustrating color coordinates of white light implemented using a red phosphor having a molar ratio of Mn of 100% and 50%,

FIG. 13 is a graph illustrating luminous flux of white light implemented using a red phosphor having a molar ratio of Mn of 100% and 50%,

FIG. 14 is a graph illustrating a spectrum of white light implemented using a red phosphor having a molar ratio of Mn of 100% and 50%,

FIG. 15 is a graph illustrating color coordinates of white light implemented using a red phosphor having a molar ratio of Mn of 100% and 30%,

FIG. 16 is a graph illustrating luminous flux of white light implemented using a red phosphor having a molar ratio of Mn of 100% and 30%,

FIG. 17 is a graph illustrating a spectrum of white light implemented using a red phosphor having a molar ratio of Mn of 100% and 30%,

FIG. 18 is a graph illustrating a spectrum of a red phosphor in which a molar ratio of Mn is adjusted to 100%, 75% and 50%.

FIG. 19 is a graph illustrating a change of luminous flux of white light under a condition of 60° C. using a red phosphor having a molar ratio of Mn of 100%, 75% and 50%,

FIG. 20 is a graph illustrating a change of a Cx color coordinate of white light under a condition of 60° C. using a red phosphor having a molar ratio of Mn of 100%, 75% and 50%,

FIG. 21 is a graph illustrating a change of a Cy color coordinate of white light under a condition of 60° C. using a red phosphor having a molar ratio of Mn of 100%, 75% and 50%,

FIG. 22 is a graph illustrating a change of luminous flux of white light under a condition of 80° C. using a red phosphor having a molar ratio of Mn of 100%, 75% and 50%,

FIG. 23 is a graph illustrating a change of a Cx color coordinate of white light under a condition of 80° C. using a red phosphor having a molar ratio of Mn of 100%, 75% and 50%,

FIG. 24 is a graph illustrating a change of Cy color coordinate of white light under a condition of 80° C. using a red phosphor having a molar ratio of Mn of 100%, 75% and 50%,

FIG. 25 is a graph illustrating a change of luminous flux of white light under a condition of 80° C. and 85% using a red phosphor having a molar ratio of Mn of 100%, 75% and 50%,

FIG. 26 is a graph illustrating a change of Cx color coordinate of white light under a condition of 80° C. and 85% using a red phosphor having a molar ratio of Mn of 100%, 75% and 50%,

FIG. 27 is a graph illustrating a change of Cy color coordinate of white light under a condition of 80° C. and 85% using a red phosphor having a molar ratio of Mn of 100%, 75% and 50%,

FIG. 28 is a conceptual diagram of a light emitting device (LED) of FIG. 8, and

FIG. 29 is a conceptual diagram of an LED package according to an embodiment of the present invention.

### MODES OF THE INVENTION

Since the present invention may make various modifications and have several embodiments, specific embodiments are illustrated and described in the drawings. However, it should be understood that it is not intended to limit embodiments of the present invention to any specific embodiment, but includes all modifications, equivalents and substitutes within the spirit and scope of embodiments.

Terms including ordinal numbers such as first, second, etc. may be used to describe various components, but the components are not limited to the terms. However, the terms are only used for the purpose of distinguishing one component from another. For example, a second component may be named as a first component, and similarly, a first component may also be named as a second component without departing from the scope of embodiments. Terms of and/or includes a combination of a plurality of related described items or any items of a plurality of related described items.

Terms used herein is for the purpose of describing a specific embodiment only and is not intended to limit embodiments of the invention. The singular forms “a,” “an,” and “the” include plural referents unless the context clearly dictates otherwise. Also, it should be understood that terms such as “including” or “having” described herein are intended to specify the presence of feature, numbers, steps, operations, components, parts, or combinations thereof described on the specification but do not preclude the presence or addition possibility of one or more other features or numbers, steps, operations, components, parts, or combinations thereof.

In the description of embodiments, when an element is referred to as being “on or under” another element, the term “on or under” refers to either a direct connection between two elements or an indirect connection between two elements having one or more elements formed therebetween. In addition, when the term “on or under” is used, it may refer to a downward direction as well as an upward direction with respect to an element.

Hereinafter, embodiments will be described in detail with reference to the accompanying drawings, the same or corresponding components are denoted by the same reference numerals, and redundant description thereof will be omitted.

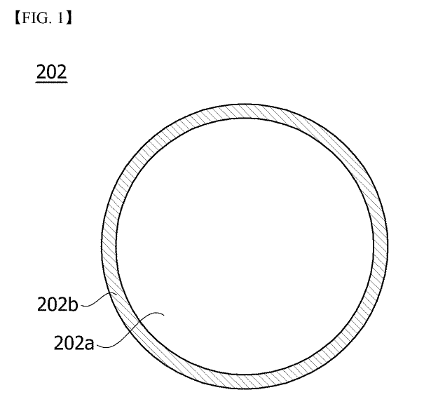

FIG. 1 is a conceptual diagram of a red phosphor according to an embodiment of the present invention.

Referring to FIG. 1, a phosphor 202 according to an embodiment may be a structure in which a coating layer 202b is formed on a surface of a particle 202a. The phosphor 202 may partially absorb excitation light and emit light in a red wavelength range. The light in the red wavelength range may have a peak at 630 to 635 nm, and a full width at half maximum (FWHM) may be 5 to 10 nm. The phosphor may be a fluoride phosphor satisfying a following structural formula.

K₂M₁₋ₓMn⁴⁺_{X}F₆ [Structural Formula]

Here, M may be at least one element selected from the group consisting of a Group IV element and a Group XIV element. In one example, M may be Si or Ti. X may satisfy 0≤X≤0.2. However, the present invention is not limited thereto, and X may satisfy 0.028≤X≤0.055. A range of X may be appropriately adjusted within the above range depending on desired luminescence characteristics or the like.

An active element, Mn, may react with air and be easily oxidized. Therefore, there is a problem that photoluminescence decreases when Mn is exposed to air for a long period of time. Accordingly, in the present embodiment, reliability can be improved by coating a surface of the phosphor.

According to an embodiment, the coating layer 202b may be formed on the surface of the particle 202a.

The coating layer 202b may include a Group III or Group IV element. The coating layer 202b may include a metal oxide such as MgO, In₂O₃, Al₂O₃, and B₂O₃. The coating layer 202b may be formed of a single layer or a plurality of layers using a metal oxide. When the plurality of layers are formed, a metal included in each layer may be different.

The coating layer 202b may be prepared by adding and mixing a phosphor powder, a coating agent, and a reaction catalyst to and with a dispersion solution, and then cleaning and drying the mixture. Hereinafter, it will be described in more detail in the following non-limiting experimental examples.

### First Experimental Example

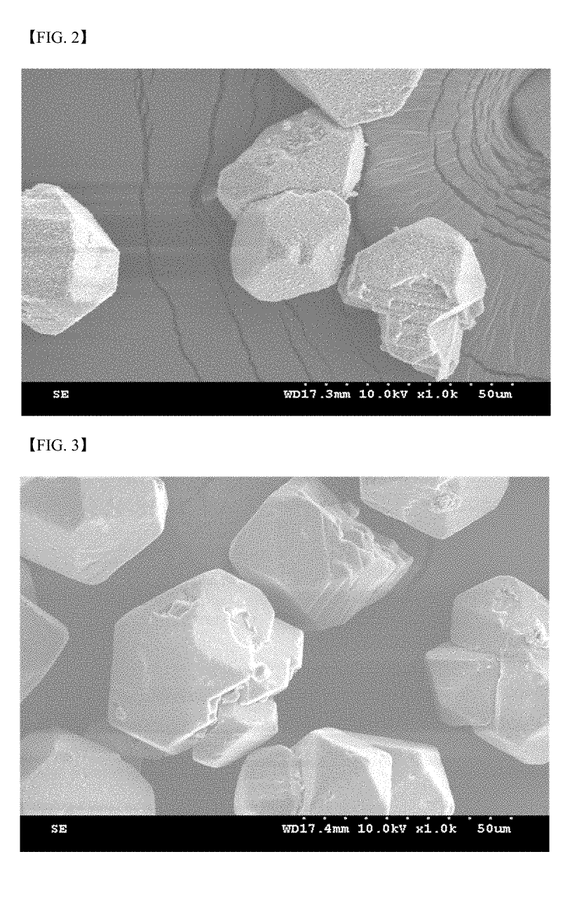

An MgO-coated red phosphor was prepared by reacting 3.0 g of KsiF phosphor, 0.5 g of Mg(C₂H₃O₂)₂, and 1 ml of a reaction catalyst (CH(CH₂)₇COOH) at 40° C. for 3 hours in 20 ml of a dispersion solution of ODE (CH₃(CH₂)₁₅CH═CH₂). Thereafter, the MgO-coated red phosphor was cleaned two times with 20 ml of IPA, and then dried at 90° C. for 1 hour. An SEM photograph of the prepared phosphor is shown in FIG. 2, and a measured photoluminescence is shown in Table 1.

### Second Experimental Example

An In₂O₃-coated red phosphor was prepared by reacting 3.0 g of KsiF phosphor, 0.5 g of In(C₂H₃O₂)₂, and 1 ml of a reaction catalyst (CH(CH₂)₇COOH) at 40° C. for 3 hours in 20 ml of a dispersion solution (CH₃(CH₂)₁₅CH═CH₂). Thereafter, the In₂O₃-coated red phosphor was cleaned two times with 20 ml of IPA, and then dried at 90° C. for 1 hour. An SEM photograph of the prepared phosphor is shown in FIG. 3, and a measured photoluminescence is shown in Table 1.

### Third Experimental Example

An Al₂O₃-coated red phosphor was prepared by reacting 4.0 g of KsiF phosphor, 0.5 g of Al(NO₃)₃, and 0.5 g of a reaction catalyst (Urea CO(NH₂)₂) at 40° C. for 3 hours in 50 ml of a dispersion solution of isopropyl alcohol (IPA). Thereafter, the Al₂O₃-coated red phosphor was cleaned two times with 20 ml of IPA, and then dried at 90° C. for 1 hour. An SEM photograph of the prepared phosphor is shown in FIG. 4, and a measured photoluminescence is shown in Table 1.

### Fourth Experimental Example

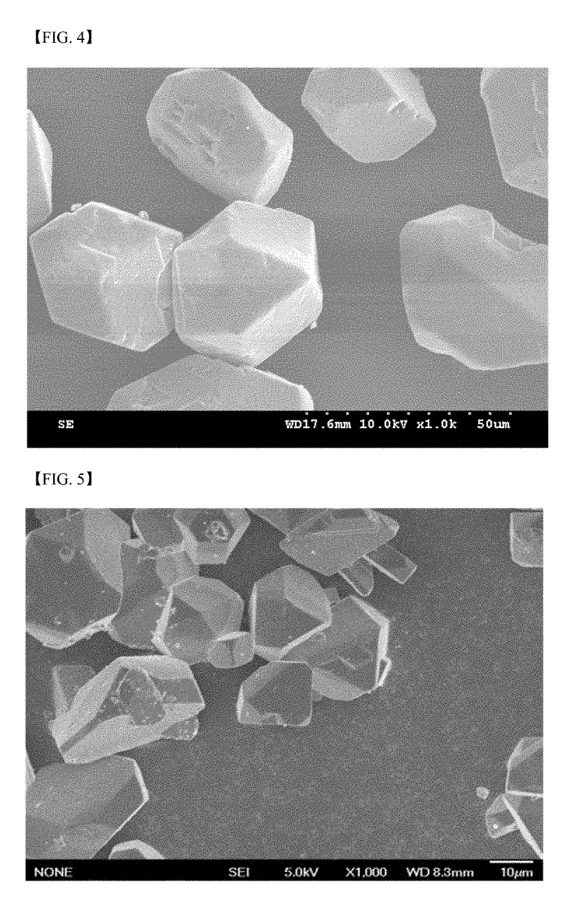

An In₂O₃-coated red phosphor was prepared by reacting 5.0 g of KsiF phosphor, 1.25 g of InCl₃, and 2.5 g of a reaction catalyst (Citric acid) at 40° C. for 3 hours in 20 ml of a dispersion solution of polyethylene glycol (PEG). Thereafter, the In₂O₃-coated red phosphor was cleaned three times with 20 ml of IPA, and then dried at 90° C. for 2 hours. An SEM photograph of the prepared phosphor is shown in FIG. 5, and a measured photoluminescence is shown in Table 1.

### Fifth Experimental Example

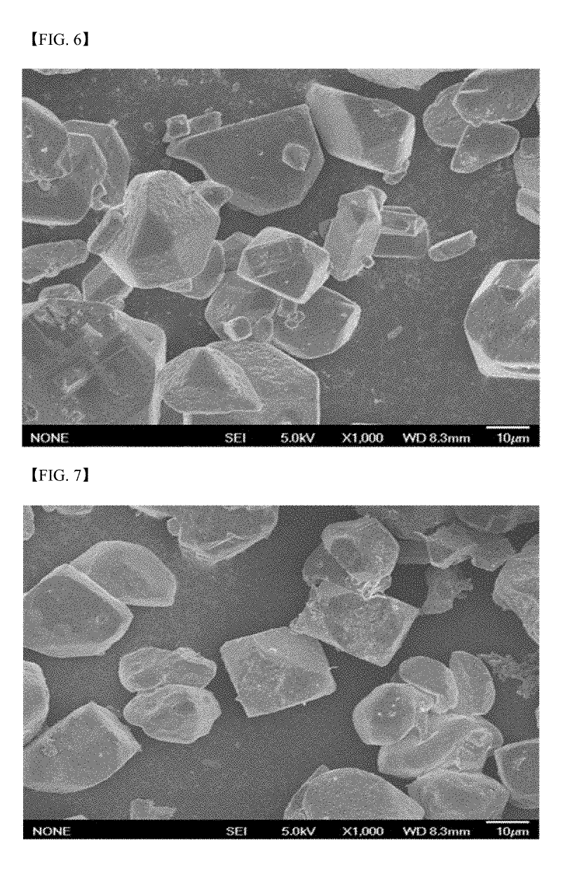

An Al₂O₃-coated red phosphor was prepared by reacting 5.0 g of KsiF phosphor, 1.25 g of Al(NO₃)₃, and 2.5 g of a reaction catalyst (Citric acid) at 40° C. for 3 hours in 20 ml of a dispersion solution of polyethylene glycol (PEG). Thereafter, the Al₂O₃-coated red phosphor was cleaned three times with 20 ml of IPA, and then dried at 90° C. for 2 hours. An SEM photograph of the prepared phosphor is shown in FIG. 6, and a measured photoluminescence is shown in Table 1.

### Sixth Experimental Example

A B₂O₃-coated red phosphor was prepared by reacting 5.0 g of KsiF phosphor, 1.25 g of Boric acid, and 2.5 g of a reaction catalyst (Citric acid) at 40° C. for 3 hours in 20 ml of a dispersion solution of polyethylene glycol (PEG). Thereafter, the B₂O₃-coated red phosphor was cleaned three times with 20 ml of IPA, and then dried at 90° C. for 2 hours. An SEM photograph of the prepared phosphor is shown in FIG. 7, and a measured photoluminescence is shown in Table 1.

TABLE 1

| | Photoluminescence (PL %) |
|---|---|
| Comparative Example | 100 |
| First Experimental Example | 93.4 |
| Second Experimental Example | 98.2 |
| Third Experimental Example | 97.8 |
| Fourth Experimental Example | 101.1 |
| Fifth Experimental Example | 98.6 |
| Sixth Experimental Example | 93.0 |

Referring to Table 1, when photoluminescence of a red phosphor (the comparative example) without coating a surface thereof is defined as 100, it can be seen that the photoluminescence of an experimental example is relatively lower. However, in the case of the fourth experimental example, it can be confirmed that the photoluminescence is higher than that of the comparative example. The second experimental example and the fourth experimental example are both coated with In, but a dispersion solution is different. Therefore, it can be seen that when the coating is performed using the PEG solution, the photoluminescence can be further increased.

Table 2 below is a table illustrating measurement of Comparative Example and Experimental Examples 4, 5, and 6, in which an intensity of luminescence decreases as a time elapses at 150° C.

TABLE 2

| | 0 h | 24 h | 48 h | 72 h | 96 h | 120 h |
|---|---|---|---|---|---|---|
| Comparative | 100 (PL %) | 50.8 | 49.8 | 44.3 | 42.7 | 42.0 |
| Example | | | | | | |
| Fourth | 100 (PL %) | 94.8 | 93.3 | 85.7 | 81.1 | 80.9 |
| Experimental | | | | | | |
| Example | | | | | | |
| Fifth | 100 (PL %) | 96.5 | 90.2 | 86.5 | 81.7 | 81.6 |
| Experimental | | | | | | |
| Example | | | | | | |
| Sixth | 100 (PL %) | 94.8 | 88.9 | 82.1 | 76.2 | 73.0 |
| Experimental | | | | | | |
| Example | | | | | | |

In the case of the comparative example in which a surface is not coated, it can be seen that the photoluminescence (PL) is decreased by about 50% when the red phosphor is exposed for 24 hours in an environment at 150° C. It can be seen that the decrease of the photoluminescence is relatively small even after a time further elapses.

However, when referring to the fourth to sixth experimental examples, it can be seen that the decrease of the photoluminescence is smaller than that of the comparative example. In particular, in the case of the fourth and fifth experimental examples, it can be seen that the luminance may be maintained at about 80% or more of an initial intensity of luminescence even after about 120 hours have elapsed.

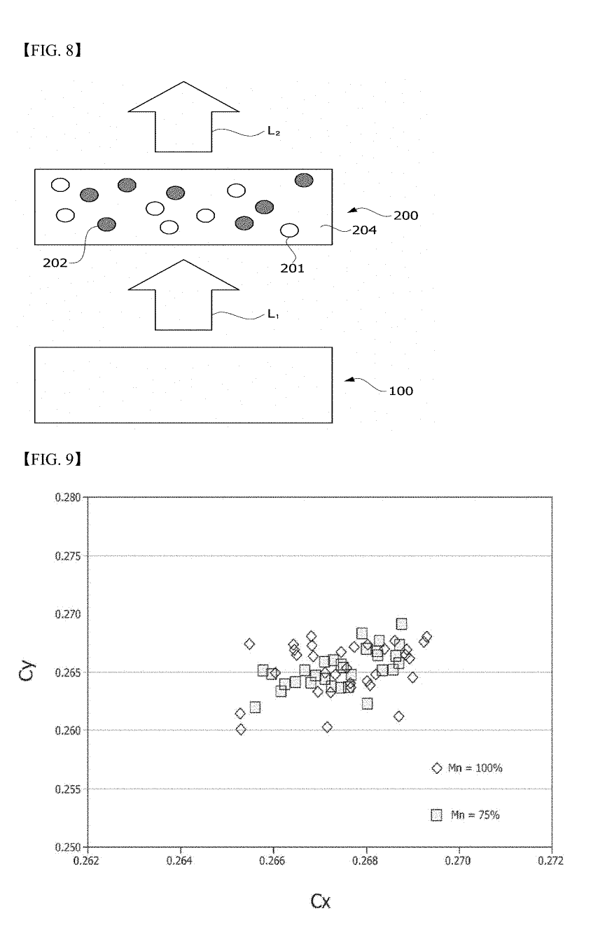

FIG. 8 is a conceptual diagram of a light emitting device according to an embodiment of the present invention.

Referring to FIG. 8, the light emitting device of an embodiment includes an LED 100 configured to emit first light L1 and a wavelength conversion layer 200 configured to absorb and emit a part of the first light L1.

The LED 100 may be a blue LED configured to emit light of 420 to 470 nm or an ultra-violate (UV) emitting element configured to emit light of an ultraviolet wavelength range. A structure of the LED 100 is not particularly limited thereto.

The wavelength conversion layer 200 includes a first phosphor 201, a second phosphor 202, and a light-transmissive resin 204 in which the first phosphor 201 and the second phosphor 202 are dispersed. A structure of the wavelength conversion layer 200 is not limited thereto.

The wavelength conversion layer 200 may be disposed only on an upper surface of the LED 100, or may be disposed on the upper surface and a side surface thereof. Alternatively, the LED 100 may be entirely molded by filling a cavity of a package.

The light-transmissive resin 204 may be selected from any one or more of the group consisting of epoxy resin, silicone resin, polyimide resin, urea resin, and acrylic resin, but is not limited thereto.

The first light L1 emitted from the LED 100 and the light converted by the wavelength conversion layer 200 may be mixed to implement white light L2 on the CIE color coordinates.

The first phosphor 201 may partially absorb the first light L1 and emit light in a green wavelength range. The light in the green wavelength range may have a peak at 525 to 545 nm, and a full width at half maximum (FWHM) may be 45 to 55 nm.

The first phosphor 201 may include at least one of β-type SiAlON:Eu, B aYSi₄N₇:Eu, Ba₃Si₆O₁₂N₂:Eu, CaSi₂O₂N₂:Eu, SrYSi₄N₇:Eu, and LuAG.

As described above, the second phosphor 202 may be a fluoride phosphor satisfying the following structural formula.

K₂M₁₋ₓMn⁴⁺_{X}F₆ [Structural Formula]

Here, M may be at least one element selected from the group consisting of a Group IV element and a Group XIV element. In one example, M may be Si or Ti. X may satisfy 0≤X≤0.2 or 0.028≤X≤0.055. Hereinafter, for convenience of explanation, the second phosphor is described as a red phosphor represented by K₂SiF₆:Mn⁴⁺.

A molar ratio x of the active element, Mn may be 0.028 to 0.055 mol. When the molar ratio of Mn is 0.04 to 0.055 mol, a total amount of the first phosphor 201 and the second phosphor 202 may be 25 to 45 wt % based on 100 wt % of a composition of the wavelength conversion layer. For example, when a total amount of the first and second phosphors is 40 wt %, a content of the light-transmissive resin 204 may be 60 wt %.

At this point, a content ratio of the first phosphor 201 may be 25 to 40%, and a content ratio of the second phosphor 202 may be 60 to 75%. When such a condition is satisfied, white light may be implemented on the CIE coordinate system. In addition, as described later, a Cx color coordinate deviation may be improved.

When the molar ratio of Mn is 0.028 to 0.399 mol, the total amount of the first phosphor 201 and the second phosphor 202 may be 30 to 50 wt % based on 100 wt % of the composition of the wavelength conversion layer. At this point, the content ratio of the first phosphor 201 may be 15 to 30%, and the content ratio of the second phosphor 202 may be 70 to 85%. When such a condition is satisfied, white light may be mixed with the light of the LED and be implemented on the CIE coordinate system. In addition, the Cx color coordinate deviation may be improved.

Hereinafter, the case where the molar ratio of Mn is 0.07 mol is defined as Mn:100%, 0.525 mol is defined as Mn:75%, 0.035 mol is defined as Mn:50%, and 0.021 mol is defined as Mn:30%.

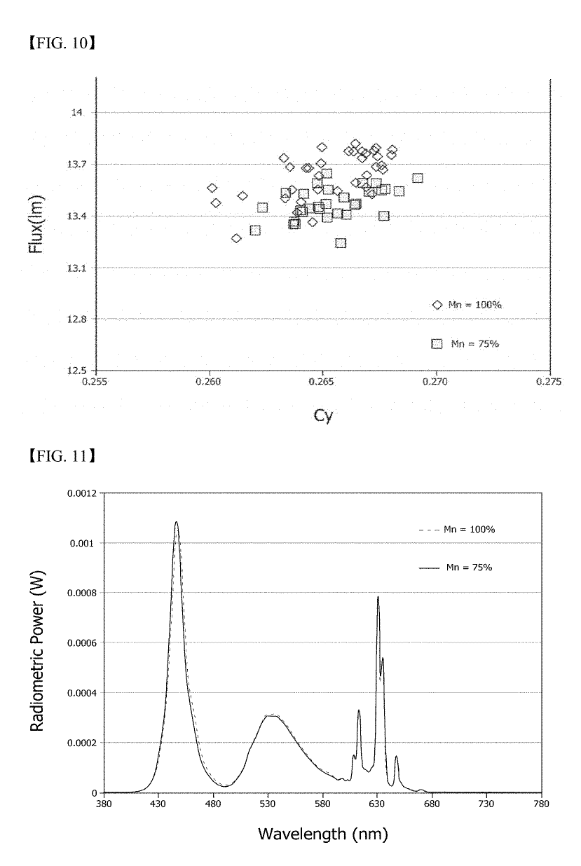

FIG. 9 is a graph illustrating color coordinates of white light implemented using a red phosphor having a molar ratio of Mn of 100% and 75%, FIG. 10 is a graph illustrating luminous flux of white light implemented using a red phosphor having a molar ratio of Mn of 100% and 75%, and FIG. 11 is a graph illustrating a spectrum of white light implemented using a red phosphor having a molar ratio of Mn of 100% and 75%.

In the comparative example, white light was implemented using a blue LED, a beta SiAlON green phosphor, and a red phosphor of Mn:100%. In the first experimental example, white light was implemented using a blue LED, a beta SiAlON green phosphor, and a red phosphor of Mn:75%.

Table 3 below is a table illustrating measurement of luminous flux, the CIE color coordinates, color reproducibility (NTSC), and wavelength peak (WP) of the white light implemented by the comparative example and the first experimental example, and Table 4 illustrates a mixing ratio of phosphor.

TABLE 3

| | Phosphor | | Flux | Flux | | | NTSC | |
|---|---|---|---|---|---|---|---|---|
| Division | Green | Red | (lm) | (%) | Cx | Cy | (%) | W · P (nm) |
| Comparative | Beta | KSF | 13.7 | 100.0 | 0.268 | 0.265 | 89.8 | 447.4 |
| Example | SiAlON | Mn: 100% | | | | | | |
| First | | KSF | 13.5 | 98.6 | 0.268 | 0.265 | 88.8 | 446.4 |
| Experimental | | Mn: 75% | | | | | | |
| Example | | | | | | | | |

TABLE 4

| | Light | Phosphor Mixing Ratio | | | |
|---|---|---|---|---|---|
| | Transmissive | | GreenBeta- | | |
| Division | Resin | Total (wt %) | SiAlON | KSFMn:100 | KSFMn:75% |
| Comparative | Silicone | 20.9 | 33.5 | 66.5 | — |
| Example | | | | | |
| First | | 25.2 | 31.2 | — | 68.8 |
| Experimental | | | | | |
| Example | | | | | |

As shown in FIG. 9, it can be seen that both the white light of the comparative example and that of the first experimental example are white light on the CIE coordinate system. In addition, as shown in FIG. 10 and Table 3, the luminous flux of the first experimental example is almost the same as that of the comparative example.

Referring to Table 4, it can be seen that in the comparative example, the total amount of the phosphor was 20.9 wt % based on 100 wt % of the total composition, whereas in the case of the first experimental example, the total amount increased to 25.2 wt %. In addition, in the case of the first experimental example, it can be seen that the content ratio of the red phosphor is 68.8%, which is slightly higher than that of the comparative example.

That is, when a molar ratio of Mn of the red phosphor is lowered, it can be seen that the total amount of the phosphor is relatively increased and the content of the red phosphor is increased in order to maintain the white light on the CIE coordinate system.

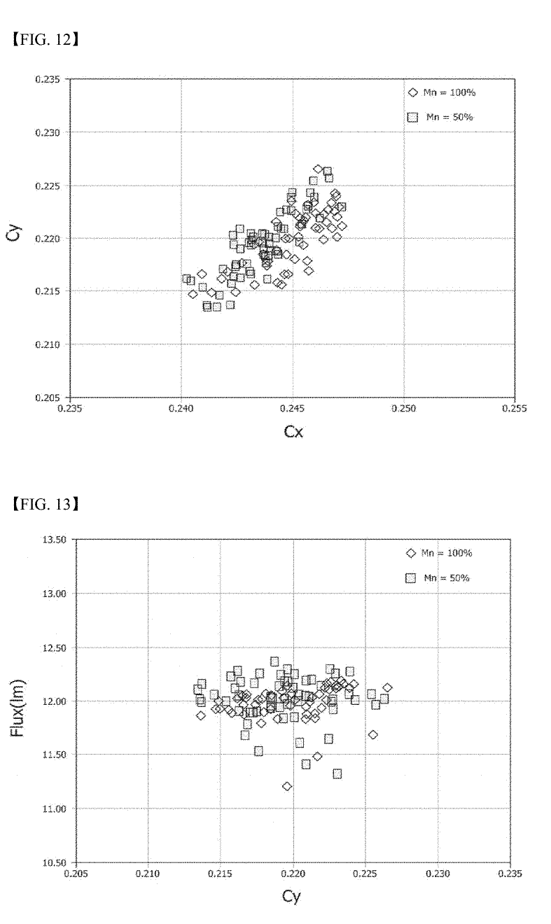

FIG. 12 is a graph illustrating color coordinates of white light implemented using a red phosphor having a molar ratio of Mn of 100% and 50%, FIG. 13 is a graph illustrating luminous flux of white light implemented using a red phosphor having a molar ratio of Mn of 100% and 50%, and FIG. 14 is a graph illustrating a spectrum of white light implemented using a red phosphor having a molar ratio of Mn of 100% and 50%.

In the comparative example, white light was implemented using a blue LED, a beta SiAlON green phosphor, and a red phosphor of Mn:100%. In the second experimental example, white light was implemented using a blue LED, a beta SiAlON green phosphor, and a red phosphor of Mn:50%.

Table 5 below is a table illustrating measurement of luminous flux, the CIE color coordinates, color reproducibility (NTSC), and wavelength peak (WP) of the white light implemented by the comparative example and the second experimental example, and Table 6 illustrates a mixing ratio of phosphor.

TABLE 5

| | Phosphor | | | Flux | | | NTSC | |
|---|---|---|---|---|---|---|---|---|
| Division | Green | Red | Flux (lm) | (%) | Cx | Cy | (%) | W · P (nm) |
| Comparative | Beta | KSF | 11.96 | 100.0 | 0.245 | 0.220 | 91.0 | 446.7 |
| Example | SiAlON | Mn: 100% | | | | | | |
| Second | | KSF | 12.07 | 100.9 | 0.244 | 0.220 | 90.7 | 446.5 |
| Experimental | | Mn: 50% | | | | | | |
| Example | | | | | | | | |

TABLE 6

| | Light | Phosphor Mixing Ratio | | | |
|---|---|---|---|---|---|
| | Transmissive | | GreenBeta- | | |
| Division | Resin | Total (wt %) | SiAlON | KSFMn:100 | KSFMn:50% |
| Comparative | Silicone | 20.0 | 32 | 68 | — |
| Example | | | | | |
| Second | | 33.0 | 18.5 | — | 81.5 |
| Experimental | | | | | |
| Example | | | | | |

As shown in FIG. 12, it can be seen that both the white light of the comparative example and that of the second experimental example are white light on the CIE coordinate system. In addition, as shown in FIG. 13 and Table 5, the luminous flux of the second experimental example is almost the same as that of the comparative example.

Referring to Table 6, it can be seen that in the comparative example, the total amount of the phosphor was 20.0 wt % based on 100 wt % of the total composition, whereas in the case of the second experimental example, the total amount increased to 33.0 wt %. In addition, in the case of the second experimental example, it can be seen that the content ratio of the red phosphor is 81.5%, which is higher than that of the comparative example.

It can be seen that the total amount of the total phosphors and the content of the red phosphor were increased in the second experimental example using Mn:50% as compared with the first experimental example.

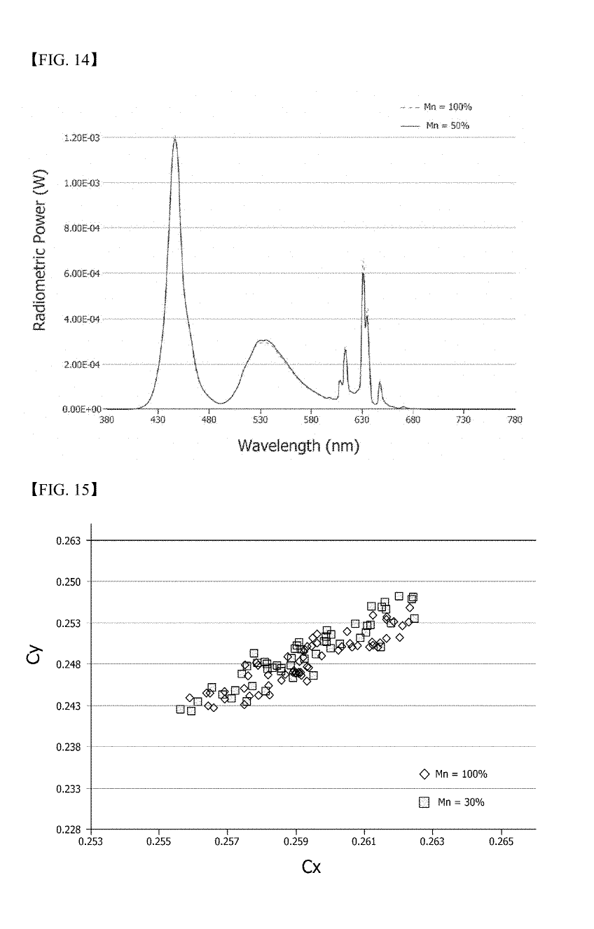

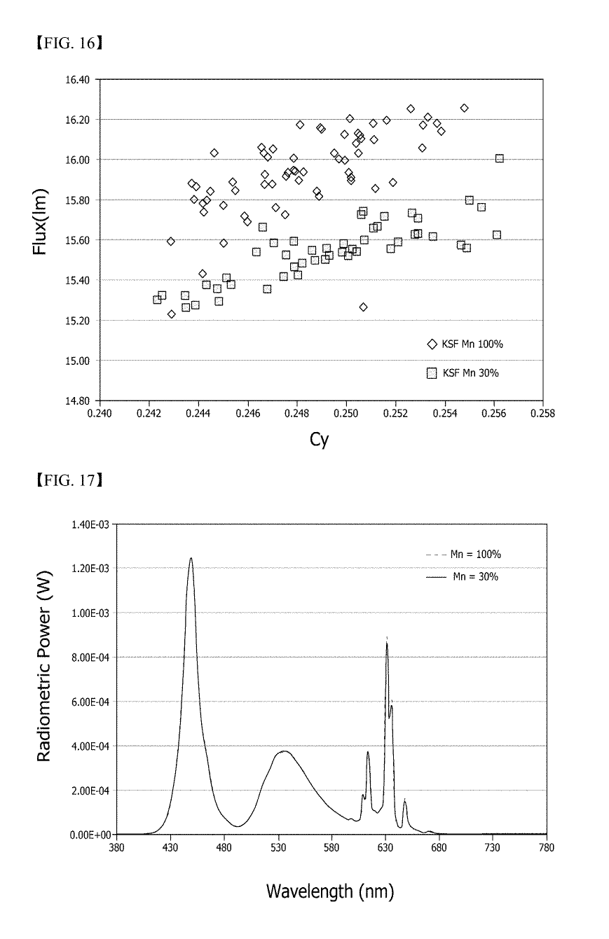

FIG. 15 is a graph illustrating color coordinates of white light implemented using a red phosphor having a molar ratio of Mn of 100% and 30%, FIG. 16 is a graph illustrating luminous flux of white light implemented using a red phosphor having a molar ratio of Mn of 100% and 30%, and FIG. 17 is a graph illustrating a spectrum of white light implemented using a red phosphor having a molar ratio of Mn of 100% and 30%.

In the comparative example, white light was implemented using a blue LED, a beta SiAlON green phosphor, and a red phosphor of Mn:100%. In the third experimental example, white light was implemented using a blue LED, a beta SiAlON green phosphor, and a red phosphor of Mn:30%.

Table 7 below is a table illustrating measurement of luminous flux, the CIE color coordinates, color reproducibility (NTSC), and wavelength peak (WP) of the white light implemented by the comparative example and the third experimental example, and Table 8 illustrates a mixing ratio of phosphor.

TABLE 7

| | Phosphor | | | Flux | | | NTSC | |
|---|---|---|---|---|---|---|---|---|
| Division | Green | Red | Flux (lm) | (%) | Cx | Cy | (%) | W · P (nm) |
| Comparative | Beta | KSF | 15.92 | 100.0 | 0.259 | 0.248 | 87.0 | 447.9 |
| Example | SiAlON | Mn: 100% | | | | | | |
| Third | | KSF | 15.55 | 97.4 | 0.259 | 0.248 | 86.6 | 447.9 |
| Experimental | | Mn: 30% | | | | | | |
| Example | | | | | | | | |

TABLE 8

| | Light | Phosphor Mixing Ratio | | | |
|---|---|---|---|---|---|
| | Transmissive | | GreenBeta- | | |
| Division | Resin | Total (wt %) | SiAlON | KSFMn:100 | KSFMn:30% |
| Comparative | Silicone | 28.5 | 31.5 | 68.5 | — |
| Example | | | | | |
| Third | | 91.0 | 10.5 | — | 89.5 |
| Experimental | | | | | |
| Example | | | | | |

As shown in FIG. 15, it can be seen that both the first white light and the second white light are white light on the CIE coordinate system. However, referring to FIG. 16 and Table 7, it can be seen that the luminous flux of the third experimental example is decreased by about 2.3% as compared with that of the comparative example.

It can be seen that in the comparative example, the total amount of the phosphor was 28.0 wt % based on 100 wt % of the total composition, whereas in the case of the third experimental example, the total amount is 91.0 wt %, which is very high. In addition, in the case of the third experimental example, it can be seen that the content ratio of the red phosphor is 89.5%, which is much higher than that of the comparative exam*.

Therefore, when a molar ratio of Mn is lowered to 30% or less, luminous flux is lowered and a total amount of the phosphor may be excessively increased. In this case, reliability problems may occur.

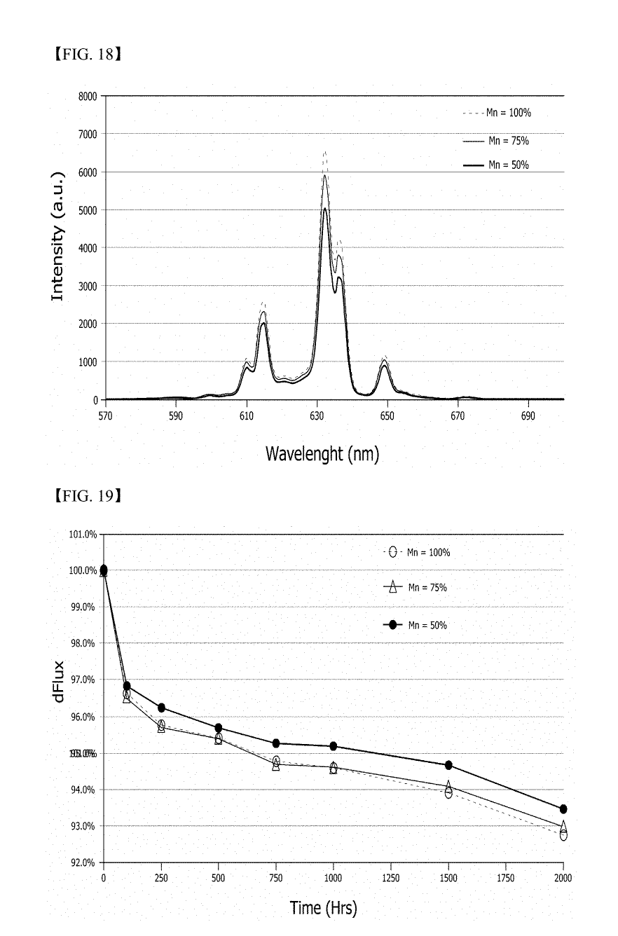

FIG. 18 is a graph illustrating a spectrum of a red phosphor in which a molar ratio of Mn is adjusted to 100%, 75% and 50%.

Table 9 below is a table illustrating measurement of wavelength peak (WP), relative luminance, full width at half maximum (FWHM), and a particle size according to a molar ratio of Mn.

TABLE 9

| | Wave- | | | | | | |
|---|---|---|---|---|---|---|---|
| | length | Relative | | Particle Size [μm] | | | |
| | Peak | luminance | FWHM | | | | D90 − |
| Division | [nm] | (%) | [nm] | D10 | D50 | D90 | D10 |
| KSF-Mn | 632 | 100 | 7 | 18 | 26 | 40 | 22 |
| 100% | | | | | | | |
| KSF-Mn | 632 | 91 | 7 | 18 | 26 | 40 | 22 |
| 75% | | | | | | | |
| KSF-Mn | 632 | 77 | 7 | 18 | 26 | 40 | 22 |
| 50% | | | | | | | |

Referring to Table 9 and FIG. 18, when the luminance of the red phosphor of which Mn is 100% is 100, it can be seen that the relative luminance of the red phosphor of Mn:75% is decreased to 91%, and the relative luminance of the red phosphor of Mn:50% is decreased to 77%. However, it can be seen that the FWHM, wavelength peak and particle size are substantially the same.

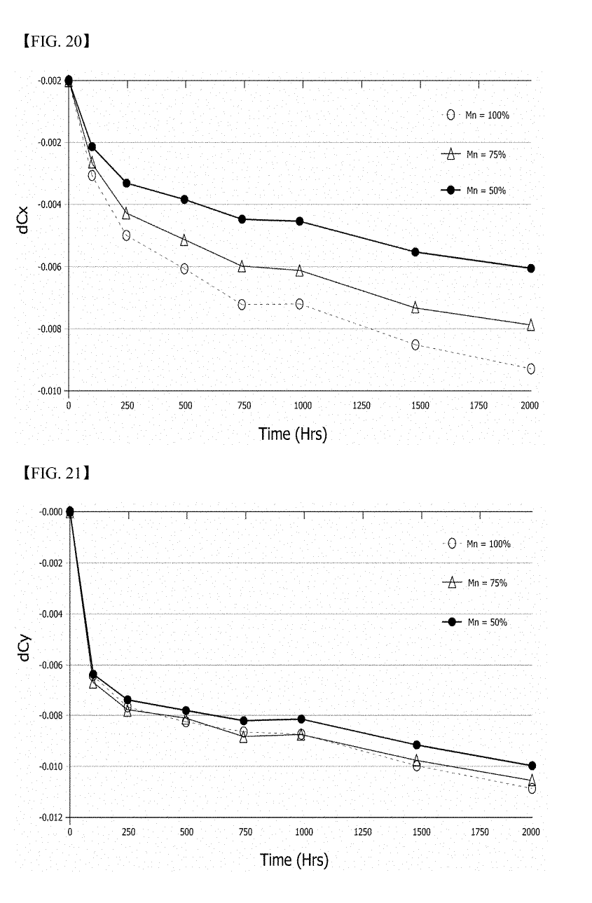

FIG. 19 is a graph illustrating a change of luminous flux of white light under a condition of 60° C. using a red phosphor having a molar ratio of Mn of 100%, 75% and 50%, FIG. 20 is a graph illustrating a change of a Cx color coordinate of white light under a condition of 60° C. using a red phosphor having a molar ratio of Mn of 100%, 75% and 50%, and FIG. 21 is a graph illustrating a change of a Cy color coordinate of white light under a condition of 60° C. using a red phosphor having a molar ratio of Mn of 100%, 75% and 50%.

Referring to FIG. 19, in the case of the third experimental example using a red phosphor having Mn of 50%, it can be seen that the variation width of the luminous flux of white light is relatively low. On the other hand, in the case of the comparative example using a red phosphor of Mn:100% and the first experimental example using a red phosphor of Mn:75%, it can be seen that a degree of decrease in the luminous flux increases as a time elapses. At this point, when the phosphor is coated with a metal oxide as described above, the decrease of the luminous flux may be more effectively reduced.

Referring to FIG. 20, in the case of the third experimental example, it can be seen that the variation width of the Cx coordinate of the white light is the lowest. In the case of the comparative example, it can be seen that the variation width of the Cx coordinate is the highest as a time elapses.

Therefore, when the molar ratio of Mn of the red phosphor is lowered, it can be seen that the reliability of the package may be improved.

However, the molar ratio of Mn of the red phosphor may be inversely proportional to the total amount of the phosphor. That is, the lower the molar ratio of Mn, the lower the Cx change rate, but an amount of the phosphor used may be increased.

However, referring to FIG. 21, it can be seen that the variation width of the Cy coordinate is relatively similar even after times elapse in the comparative example, the first experimental example, and the second experimental example.

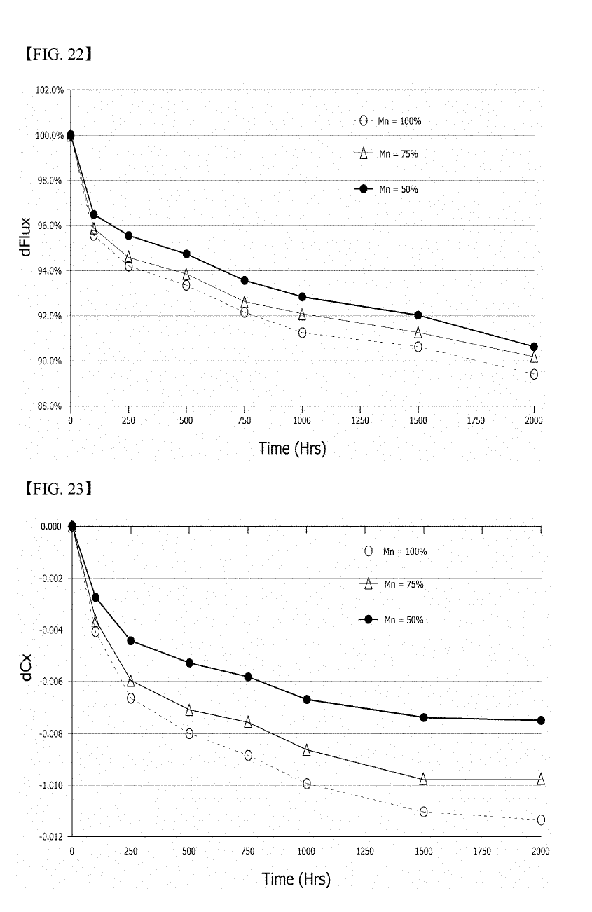

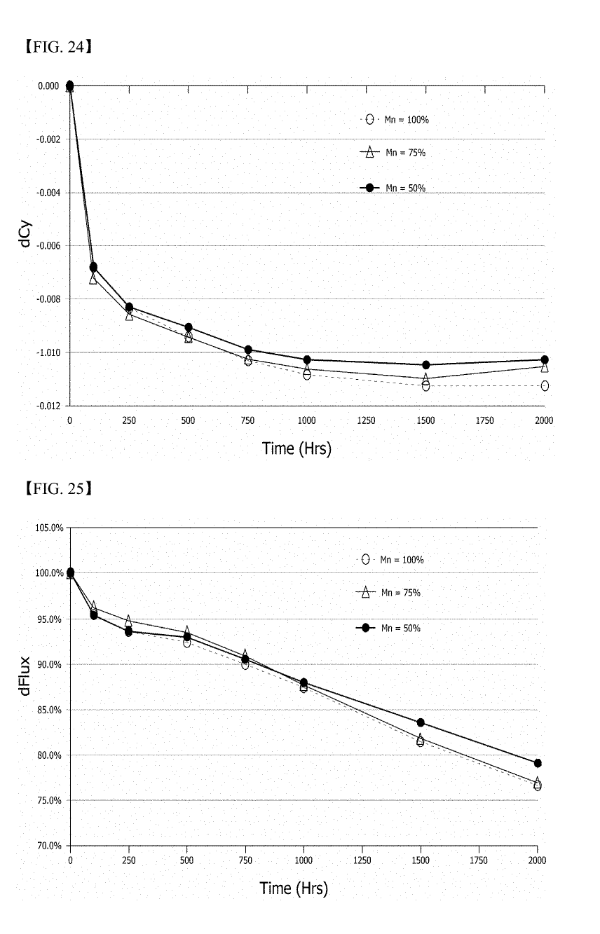

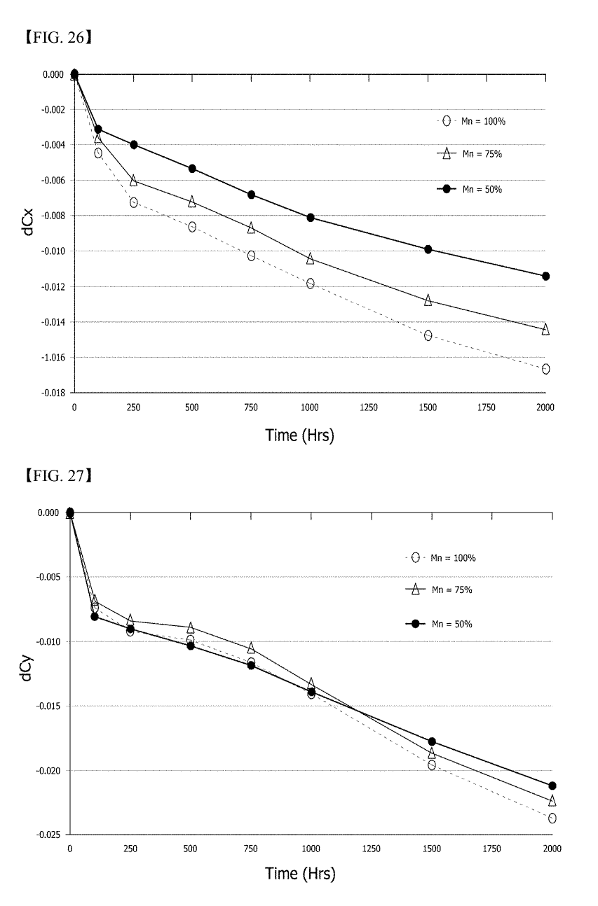

As shown in FIGS. 22 to 24, even when a temperature is further raised to 80° C., similar result values could be obtained in the deviation of such luminous flux, Cx color coordinate, and Cy color coordinate. In addition, as shown in FIGS. 25 to 27, similar result values could be obtained even under the condition of high temperature/high humidity (80° C./85%).

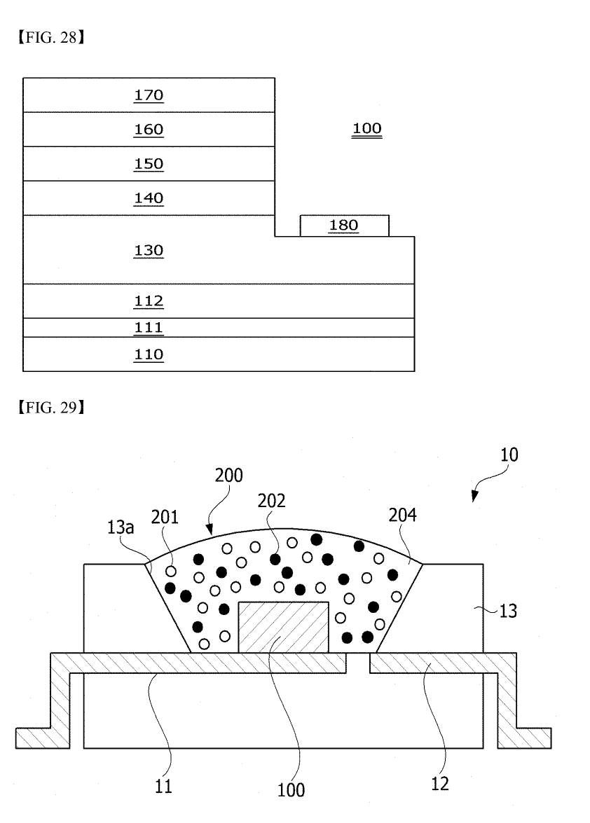

FIG. 28 is a conceptual diagram of LED of FIG. 8, and FIG. 29 is a conceptual diagram of an LED package according to an embodiment of the present invention.

Referring to FIG. 28, a substrate 110 of the LED 100 includes a conductive substrate or an insulating substrate. The substrate 110 may be a material suitable for growing a semiconductor material or a carrier wafer. The substrate 110 may be formed of a material selected from sapphire (Al₂O₃), SiC, GaAs, GaN, ZnO, Si, GaP, InP, and Ge, but is not limited thereto.

Buffer layers 111 and 112 may mitigate lattice mismatch between a light-emitting structure provided on the substrate 110 and the substrate 110. The buffer layers 111 and 112 may be grown as a single crystal on the substrate 110, and the buffer layers 111 and 112 grown as the single crystal may improve the crystallinity of a first semiconductor layer 130.

The light-emitting structure provided on the substrate 110 includes the first semiconductor layer 130, an active layer 140, and a second semiconductor layer 160. In general, the above-described light-emitting structure may be divided into a plurality of pieces by cutting the substrate 110.

The first semiconductor layer 130 may be a compound semiconductor such as a group III-V or a group II-VI, and the first semiconductor layer 130 may be doped with a first dopant. The first semiconductor layer 130 may be a semiconductor material having a composition formula of Inx1Aly1Ga1-x1-y1N (0≤x1≤1, 0≤y1≤1, 0≤x1+y1≤1), for example, may be selected from GaN, AlGaN, InGaN, InAlGaN, or the like. The first dopant may be an n-type dopant such as Si, Ge, Sn, Se or Te. When the first dopant is an n-type dopant, the first semiconductor layer 130 doped with the first dopant may be an n-type semiconductor layer.

The active layer 140 is a layer where electrons (or holes) injected through the first semiconductor layer 130 and holes (or electrons) injected through the second semiconductor layer 160 meet. As the electrons and the holes recombine, the active layer 140 may transit to a low energy level and may generate light having a wavelength corresponding thereto. There is no limitation on a light-emitting wavelength in the present embodiment.

The active layer 140 may have any one of a single-well structure, a multi-well structure, a single-quantum-well structure, a multi-quantum-well (MQW) structure, a quantum-dot structure, and a quantum-wire structure, but the structure of the active layer 140 is not limited thereto.

The active layer 140 may have a structure in which a plurality of well layers and barrier layers are alternately arranged. The well layer and the barrier layer may have a composition formula of InxAlyGa1-x-yN (0≤x≤1, 0≤y≤1, 0≤x+y≤1), and an energy band gap of the barrier layer may be greater than that of the well layer.

The second semiconductor layer 160 may be formed on the active layer 140 and may be implemented as a compound semiconductor such as a group III-V or a group II-VI, and the second semiconductor layer 160 may be doped with a second dopant. The second semiconductor layer 160 may be formed of a semiconductor material having a composition formula of Inₓ₅Al_{y2}Ga_{1-x5-y2}N (0≤x5≤1, 0≤y2≤1, 0≤x5+y2≤1) or may be formed of a material selected from AlInN, AlGaAs, GaP, GaAs, GaAsP, AlGaInP, or the like. When the second dopant is a p-type dopant such as Mg, Zn, Ca, Sr, or Ba, the second semiconductor layer 160 doped with the second dopant may be a p-type semiconductor layer.

An electron blocking layer (EBL) 150 may be disposed between the active layer 140 and the second semiconductor layer 160. The EBL 150 may block a flow of electrons supplied from the first semiconductor layer 130 to the second semiconductor layer 160 and may increase probability that electrons and holes recombine in the active layer 140. An energy band gap of the EBL 150 may be greater than that of the active layer 140 and/or the second semiconductor layer 160.

The EBL 150 may be formed of a semiconductor material having a composition formula of Inₓ₁Al_{y1}Ga_{1-x1-y1}N (0≤x1≤1, 0≤y1≤1, 0≤x1+y1≤1), for example, may be selected from AlGaN, InGaN, InAlGaN, or the like.

A first electrode 180 may be formed on an exposed part of the first semiconductor layer 130. In addition, a second electrode 170 may be formed on the second semiconductor layer 160. Various metal and transparent electrodes may be applied to the first electrode 180 and the second electrode 190.

The first electrode 180 and the second electrode 170 may include any one of metals selected from In, Co, Si, Ge, Au, Pd, Pt, Ru, Re, Mg, Zn, Hf, Ta, Rh, Ir, Cr, Mo, Nb, Al, Ni, Cu, and WTi. The first electrode 180 and the second electrode 170 may further include an ohmic electrode layer as necessary.

Referring to FIG. 29, an LED package 10 according to an embodiment includes a first lead frame 11, a second lead frame 12, an LED 100, a wavelength conversion layer 200, and a body 13.

An LED having various structures that emit light in a blue or an ultraviolet wavelength range may be applied to the LED 100. In addition, the configuration described in FIG. 28 may be applied to the LED 100 as it is.

The LED 100 may be electrically connected to the first lead frame 11 and the second lead frame 12. An electrical connection between the LED 100 and the first and second lead frames 11 and 12 may be determined by an electrode structure (vertical or, horizontal) of the LED.

The body 13 includes a cavity 13a to which the first lead frame 11 and the second lead frame 12 are fixed and the LED 100 is exposed. The body 13 may include a polymer resin such as polyphthalamide (PPA).

The wavelength conversion layer 200 is disposed in the cavity 13a and includes first and second phosphors 201 and 202. The first and second phosphors 201 and 202 may be dispersed in the light-transmissive resin 204. The wavelength conversion layer 200 may include the above-described characteristics as it is.

The light emitting device or the LED package of an embodiment may further include an optical member such as a light guide plate, a prism sheet, and a diffusion sheet to function as a backlight unit. In addition, the LED of an embodiment may be further applied to a display device, a lighting device, and an indicating device.

At this point, the display device may include a bottom cover, a reflection plate, a light-emitting module, a light guide plate, an optical sheet, a display panel, an image signal output circuit, and a color filter. The bottom cover, the reflective plate, the light-emitting module, the light guide plate, and the optical sheet may form a backlight unit.

The reflection plate is disposed on the bottom cover, and the light-emitting module emits light. The light guide plate is disposed in front of the reflection plate to guide light emitted from the light-emitting module forward, and the optical sheet includes a prism sheet or the like and is disposed in front of the light guide plate. The display panel is disposed in front of the optical sheet, the image signal output circuit supplies an image signal to the display panel, and the color filter is disposed in front of the display panel.

In addition, the lighting device may include a substrate, a light source module including the LED of an embodiment, a heat dissipating unit configured to dissipate heat of the light source module, and a power supply unit configured to process or convert an electrical signal provided from the outside and provide the processed or converted electrical signal to the light source module. Further, the lighting device may include a lamp, a headlamp, or a street lamp or the like.

Embodiments of the present invention described above are not limited to the above-described embodiments and the accompanying drawings. It will be apparent to those skilled in the art to which the present embodiment of the present invention belongs that multiple substitutions, modifications and changes are possible without departing from the technical idea of embodiments.

1. A red phosphor comprising a coating layer formed on a surface, and
the red phosphor satisfies a following structural fog formula:
K₂M₁₋ₓMn⁴⁺_{X}F₆ [Structural Formula]
wherein M is at least oils element selected from the group consisting of a Group IV element and a Group XIV element, and the X satisfies 0.028≤X≤0.055.

2. The red phosphor of claim 1,
wherein the coating layer includes a metal oxide.

3. The red phosphor of claim 2, wherein the coating layer comprises a plurality of metal oxide layers and a metal included in each layer is different.

4. The red phosphor of claim 2, wherein the coating layer comprises at least one of MgO, In₂O₃, Al₂O₃, and B₂O₃.

5. A light emitting device comprising:
a light emitting device (LED) configured to emit first light; and
a wavelength conversion layer configured to convert a wavelength of the first light,
wherein the wavelength conversion layer comprises:
a first phosphor configured to absorb the first light to emit light in a green wavelength range; and
a second phosphor configured to absorb the first light to emit light in a red wavelength range,
wherein the second phosphor satisfies a following structural formula:
K₂M₁₋ₓMn⁴⁺_{X}F₆ [Structural Formula]
wherein M is at least one element selected from the group consisting of a Group IV element and a Group XIV element, and the X satisfies 0.028≤X≤0.055.

6. The light emitting device of claim 5, wherein the wavelength conversion layer comprises a light-transmissive resin in which a first wavelength converter and a second wavelength converter are dispersed.

7. The light emitting device of claim 5, wherein a total amount of the first wavelength converter and the second wavelength converter is 25 to 50 wt % based on 100 wt % of a composition of the wavelength conversion layer.

8. The light emitting device of claim 6, wherein a total amount of the first wavelength converter and the second wavelength converter is 25 to 45 wt % based on 100 wt % of a composition of the wavelength conversion layer.

9. The light emitting device of claim 8, wherein a content ratio of the first wavelength converter is 25 to 40%, and a content ratio of the second wavelength converter is 60 to 75%.

10. The light emitting device of claim 8, wherein a molar ratio of Mn of the second wavelength converter is 0.04 to 0.055 mol.

11. The light emitting device of claim 1, wherein a total amount of the first wavelength converter and the second wavelength converter is 30 to 50 wt % based on 100 wt % of a composition of the wavelength conversion layer.

12. The light emitting device of claim 11, wherein a content ratio of the first wavelength converter is 15 to 30%, and a content ratio of the second wavelength converter is 70 to 85%.

13. The light emitting device of claim 12, wherein a molar ratio of Mn of the second wavelength converter is 0.028 to 0.399 mol.

14. The light emitting device of claim 5, wherein the second phosphor comprises a coating layer formed on a surface.

15. The light emitting device of claim 14, wherein the coating layer comprises at least one of MgO, In₂O₃, Al₂O₃, and B₂O₃.
